(19) United States
(12) Patent Application Publication
(10) Pub. No.: US 2015/0219734 A1
(43) Pub. Date: Aug. 6, 2015

(54) POROUS AND STRUCTURED MATERIALS FOR DYNAMIC NUCLEAR POLARIZATION, PROCESS FOR THEIR PREPARATION AND NMR ANALYSIS METHOD

(71) Applicants: UNIVERSITE CLAUDE BERNARD LYON I, Villeurbanne Cedex (FR); CENTRE NATIONAL DE LA RECHERCHE SCIENTIFIQUE, Paris Cedex 16 (FR); ETH ZURICH, Zurich (CH)

(72) Inventors: David Gajan, Villeurbanne (FR); Christophe Coperet, Zurich (CH); Chloe Thieuleux, Villeurbanne (FR); Lyndon Emsley, Saint Martin Le Vinoux (FR); Anne Lesage, Rillieux (FR)

(21) Appl. No.: 14/601,628

(22) PCT Filed: Aug. 2, 2013
(86) PCT No.: PCT/EP2013/066279

§ 371 Date: Jan. 21, 2015

(30) Foreign Application Priority Data
Aug. 6, 2012 (IB) PCT/IB2012/002128

(51) Int. Cl. G01R 33/48; C08L 83/08; G01R 33/60

(52) U.S. Cl. CPC G01R 33/4828; G01R 33/60; C08L 83/08

(57) ABSTRACT

The present invention concerns materials consisting in a porous and structured network, this network being at least in part formed by Si atoms, or Si atoms and metal atoms, linked to each other's via siloxy bonds, the amount of radical ranging from 0.50 to 0.03 mmol of radical per gram of material, and in that the network is formed with a sol-gel step using an organosilane for the introduction of the organic molecules allowing their regular distribution within the porous structured material.

The invention also concern a process for the preparation of such material and a method of analysis by Nuclear Magnetic Resonance (NMR) of an analyte wherein it uses dynamic nuclear polarization generated with a material according to the invention.

This invention relates to the field of nuclear magnetic resonance (NMR) spectroscopy and, in particular, to materials adapted for the achievement of dynamic nuclear polarization (DNP). The present invention concerns new materials which incorporate persistent radicals that are covalently linked to a structured and porous silica network and methods of liquid or nuclear magnetic resonance which use such materials.

Nuclear magnetic resonance (NMR) spectroscopy is a method of chemical analysis that can reveal information on molecular structure and geometrical arrangement in space. NMR is however an intrinsically insensitive analytical technique because the detected signal is proportional to a very weak population difference between two nuclear energy levels. One way to improve the sensitivity is to increase the difference in energy levels by employing high magnetic fields, the sensitivity increasing with the field to the power 3/2. But even under ultra-high field magnets (21 T), the number of atoms whose spin magnetic moment is oriented in the direction of the magnetic field is only lightly larger than those polarized against (in the opposite direction of) the field. This small excess of ground state nuclei gives the sample only a small overall polarization in the direction of the magnetic field. Other efforts to increase the sensitivity of NMR include adding together the results of many spectra of the same sample so that the signal may be enhanced in comparison with random noise at the cost of longer analysis time. Particularly useful for this purpose is the Fourier Transform method (U.S. Pat. No. 3,475,680).

Recently the technique of dynamic nuclear polarization (DNP) has been used to increase the nuclear magnetic polarization of the sample, and thereby increase the sensitivity of the NMR experiment. DNP can be used to enhance the intensity of NMR signals, since NMR signals arise from transitions between nuclear spin states which have a very low energy difference and which are thus very weakly polarized at room temperature, leading to weak signals.

DNP refers to all the methods where the electron spin polarization is transferred to nuclear spins by the application of a resonant microwave excitation of the electronic spin transitions, including magnetic resonance imaging (Golman et al. PNAS Jul. 25, 2006, vol 103 n° 30, 11270-11275). The technique relies on the use of presence of unpaired electrons, which are more highly polarized in a magnetic field than most nuclei owing to the much larger gyromagnetic ratio of the electron compared with nuclei. Unpaired electrons are thus roughly 660 times more polarized than proton spins under the same conditions. DNP is the method whereby electron polarization is transferred to nuclei. This polarization can be transferred to the nuclei of the sample when the microwave irradiation is sufficient to induce transitions between the electron magnetic energy levels of the polarizing agent.

Currently, two main approaches can be applied to obtain highly polarized nuclear spins in solution by DNP.

Overhauser induced DNP (<<ODNP>>) is an established technique with the first experiments dating back decades (Overhauser, 1953). Solutions that contain a polarizing agent with unpaired electrons (a radical) can be directly hyperpolarized by this approach. This effect is however limited to low magnetic fields, typically 0.35 T (above 1 T, the modulation of the electron-nuclei dipolar couplings is not efficient for magnetization transfer by the Overhauser effect). It has been shown by Griffin and coworkers (G. J. Gerfen et al. J. Chem. Phys. 1995, 102, 9494 and D. A. Hall et al. Science 1997, 276, 930) that, at higher magnetic field and in particular cases where a scalar coupling is established between the electron and a nucleus, the modulation of this through-bond interaction can give rise to a Overhauser effect and to significant NMR signal amplification. The ODNP approach is typically applied to probe the dynamics of water molecules in close proximity to an electron spin label (5 to 10 Å) (B. D. Armstrong, S. Han, J. Am. Chem. Soc., 2009, 131, 4641). More recently, ODNP has been performed at high magnetic fields using either i) shuttle DNP spectrometers, which enables to excite the electron spins at low magnetic and then shuttles the sample to high magnetic field for NMR detection (M. Reese et al, J. Am. Chem. 2009 Soc. 131, 15086-15087) or ii) a high-field DNP spectrometer, which performs simultaneously the microwave excitation and NMR detection and where the sample is contained in small capillaries of a few nanoliters (Denysenkov, et al, Appl. Magn. Reson. 2008, 34 289-299; C. Griesinger et al, Progress in Nuclear Magnetic Resonance Spectroscopy 2012, 64, 4-28).

3. H. Ardenkjær-Larsen et al developed a more recent approach (3. H. Ardenkjær-Larsen et al, PNAS, 2003, 100, 10158-10163), in which the polarization of the nuclear spins is performed at low temperature in the solid-state. The sample is then (i) either studied directly using solid-state NMR techniques, often using magic angle spinning, or (ii) is dissolved rapidly to obtain a solution in which the nuclear spins of the molecules of interest are strongly polarized. The sensitivity increase was achieved by the use of a polarizing agent containing unpaired electron(s) with a doublet electronic state. The polarizing agent was dissolved in a solution containing the substance to be analyzed, and the solution cooled to 1.5 Kelvin in a polarizing magnetic field of 3.35 Tesla. The cold solution was irradiated with radio frequency radiation at the Larmor frequency of the electron (94 GHz). Then the sample was warmed by the addition of room temperature solvent, and the spectra obtained within a few seconds after addition of the solvent. The irradiation step transferred the high polarization of the unpaired electron of the free radical to the nuclei of the sample and the hyper polarization was retained for several seconds while the sample was warmed and dissolved in the diluting solvent. The solid-state NMR experiments make use of polarization in situ inside the NMR spectrometer. The dissolution experiment is usually performed in an ex situ DNP polarizer, consisting in a magnet, a cryostat to cool down the sample to a temperature often close to 1.5 K and a microwave source. After polarization by microwave irradiation, and rapid dissolution, the hyperpolarized liquid sample is transferred to a high-resolution NMR spectrometer, where the NMR signal is detected. The NMR signals can be amplified by factors larger than 10 000. The radicals used to obtain the polarization can either be neutralized chemically or filtered out of solution. This method has been mostly be used for low-nuclei (¹³C and ¹⁵N) and the detection of hyper-polarized protons using dissolution DNP remains challenging due to the shorter nuclear relaxation times. Single scan methods have been applied to obtain multi-dimensional correlation spectra.

Others authors describe the use of radicals on solid supports to (hyper)polarize solutions and flowing fluids by DNP. First, Dorn et al., in J. Am. Chem. Soc. 110, 2294 (1988); Anal. Chem. 70, 2623-2628 (1998) have studied the polarization of several flowing organic solvents by ODNP using TEMPO immobilized on polymer beads and silica gel. This approach is dubbed SLIT DNP for flow Solid-Liquid Intermolecular Transfer DNP. The advantage of this approach is that a radical-free hyperpolarized solution is obtained. In favorable cases, ¹³C (scalar-dominated) enhancements of 1-2 orders of magnitude could be obtained (for example in mixtures of benzene and several chlorocarbons which were continuously “recycled” through the DNP spectrometer). This approach is however not general (i.e. is limited to cases where a transient coupling with the radical occurs) and a complex apparatus is needed.

An agarose gel containing covalently bound radicals (TEMPO) has also been developed by S. Han et al. (JMR, 2008, 190, 307-315) to polarize aqueous solutions (stagnant or in continuous flow) by ODNP, at room temperature and low magnetic field (0.35 T). The mobility of the radicals in the gel is sufficient for efficient polarization transfer via the Overhauser effect, without the radicals being released into the solution. However, as the radicals are immobilized and the mobility of the solution is reduced within the gel, the proton enhancements observed for the water signal are lower than those obtained when TEMPO is directly dissolved in the sample. This method has so far been limited to the enhancement of the water NMR signal.

In the both techniques developed by Dorn et al. and Hans et al., the solution is polarized at low field before being subsequently transported into a high-resolution magnet. Therefore, this approach is an ex-situ polarization technique. The method has not been demonstrated yet as a general approach to detect small concentrations of substrates in solutions.

More recently Lafon et al. described in Applied Magn. Reson. 2012, 43, 237 the use of in situ solid-state DNP NMR to polarize a commercially available TEMPO containing solid support, SiliaCAT® TEMPO which is a non-structured material containing 0.7 mmol radicals by grams of material. The sample did not contain any other component, and the notion of polarizing a substrate or an analyte of interest with such a material is not considered.

Other non-structured materials comprising TEMPO groups are also used as catalytic materials for selective oxidation of alcohols (U.S. Pat. No. 6,797,773).

In this context, an objective of the invention is to propose a solid-phase polarization medium for DNP, that could substantially simplify the steps to be performed in order to obtain NMR data, especially when solid NMR is used. The proposition of a solid-phase polarization medium will also facilitate the quality of spectra obtained by rendering the separation of the substrate and the polarization agent straightforward.

Another purpose of the invention is to offer a new solid-phase polarization medium that could yield to larger sensitivity factors than the conventional protocols.

The invention concerns materials consisting in a porous and structured network, this network being at least in part formed by Si atoms, or Si atoms and metal atoms, linked to each other's by oxy bridges, which comprise organic molecules including at least one radical and being covalently bonded to the network by siloxy bonds, the amount of radicals ranging from 0.50 to 0.03 mmol of radical per gram of material, for instance from 0.25 to 0.09, from 0.25 to 0.06, or from 0.25 to 0.03 mmol of radical per gram of material. In the materials according to the invention, the network is formed with a sol-gel step using an organosilane for the introduction of the organic molecules allowing their regular distribution within the porous structured material.

The Si atoms, or the Si atoms and the metal atoms when they are present, linked to each other's by oxy bridges, constitute the inorganic part of the material and formed an inorganic oxide.

Preferably, more than 50% of the organic molecules are covalently bonded to the network via three siloxy bonds.

According to a preferred embodiment, the mean pore diameter of the materials according to the invention belongs to the range from 35 Å to 500 Å.

The organic molecules which include at least one radical are located in the mass of the material, and can be localized:
either in the pores of the material and in this case the network is only formed by Si atoms, or Si atoms and metal atoms, linked to each other's by oxy bridges, or
in the walls of the material and in that case the network is formed by (Si atoms, or Si atoms and metal atoms, linked to each other's by oxy bridges and also by the organic molecules.

Advantageously, the network of the material or its inorganic part is made of silica SiO₂, alumina Al₂O₃, TiO₂ or ZrO₂.

As preferred embodiments, a material according to the invention is obtainable by a sol-gel method involving at least two precursors:
a tetraalkoxysilane, tetrahydroxysilane, alkoxymetal, hydroxymetal, alkoxyhydroxysilane, al koxyhydroxymetal, silicate or metallate in which the metal is Zr, Ti or Al,
and an organosilane corresponding to a monosilyl or a polysilyl entity, for instance chosen among the organotrialkoxysilanes, organotrichlorosilanes, organotris(methallyl)silanes, organotrihydrogenosilanes, di-organosilane such as diorganodialkoxy or dichlorosilane, or disilyl compounds of general formula (Xa)₃Si—R′—Si(Xa)₃ with Xa=halogen, alkoxy, hydroxyl, methallyl or hydrogen, the selected organosilane carrying the organic moiety which includes at least one radical or carrying a reactive function allowing, in one or several additional step(s), the introduction of the organic molecules which include at least one radical, and in particular with the preferred conditions described hereafter.

For instance, the organosilane used for the introduction of the organic molecule which includes at least one radical, is carrying a reactive function selected from halogen atoms and functional groups such as azide, amine, amide, imine, nitrosyl, carboxyl, ketone, aldehyde, phosphine, phosphate, phosphinite, sulfoxide, —OH, —SH, and ether.

In order to obtain the organization of the material, the sol-gel step is performed with a structure directing agent. In this case, the material obtained by the sol-gel method can be treated to remove the structure directing agent, before the step(s) carried for linking the organic molecule which includes at least one radical by reaction on the reactive function.

In general, the sol-gel method is achieved, with a structure directing agent, in water with or without at least one co-solvent or in an appropriate polar solvent along with water, using hydrolysis-condensation catalysts chosen among bases, acids or nucleophilic compounds. The sol-gel method used for the preparation of the materials according to the invention is preferably achieved, with a structure-directing agent chosen among:
alkylpolyethyleneoxides or alkylarylpolyethylene oxides (preferably C₁₆H₃₃O(CH₂CH₂O)₂H, C₁₁₋₁₅H₂₃₋₃₁O(CH₂CH₂O)₁₂H, C₁₄H₂₂O(C₂H₄O)ₙH, n=9-10), p-C₈H₁₇C₆H₄O(CH₂CH₂O)₁₀H, C₁₂H₂₅O(CH₂CH₂O)ₙH
polysorbate surfactants (polyoxyethylene (20) sorbitan monolaurate) and,
amphiphilic block copolymers (preferably triblock copolymers such as EO₂₀-PO₇₀-EO₂₀, EO₁₀₀-PO₇₀-EO₁₀₀ or such as EO₁₃₂-PO₅₀-EO₁₃₂).

The ratio (numbers of radical)/(total number of Si atoms and metal atoms when they are present) preferably belongs to the range from 1/27 to 1/500, for instance from 1/62 to 1/180 or 1/62 to 1/500. Such a ratio number can be determined by elemental analysis coupled with RPE.

Examples of materials according to the invention comprise at least one organic-inorganic component (I) distributed within its porous silica network of formula (I):

(O_{1,5}Si-LₘYL′-SiO_{1,5})ₙ (I)

wherein

Y is a moiety, which includes at least one radical,

L and L′ can be identical or different and are connecting organic moiety,

n and m can be identical or different and are integers selected as 1≦m+n<5,

the SiO_{1,5} are part of the inorganic part of the network.

Such materials can also comprise at least one organic-inorganic component (II) distributed within its porous silica network of formula (II):

(O_{1,5}Si-LₘXL′-SiO_{1,5})ₙ (II)

wherein

X is a moiety including at least one reactive function allowing, in one or several additional step(s), the introduction of at least one radical,

L and L′ can be identical or different and are connecting organic moiety, n and m can be identical or different and are integers selected as 1≦m+n<5,

the SiO_{1,5} are part of the inorganic part of the network.

For clarifying the reading of formula (I) and (II), when m=2, for instance, it means that respectively Y or X are covalently bonded by two different covalent bonds to two -L-SiO_{1,5} groups.

SiO_{1,5} is used in order to indicate that the 3 Si—O bonds are shared between the inorganic-inorganic compound (I) (or (II) and the inorganic network, which is classically used by the man skilled in the art.

L and L′, identical or different, can be, for instance, hydrocarbonated connecting moiety which can be linear, branched or include a cycle, which can be saturated or unsaturated, substituted or non-substituted, and which can include, in its chain or cycle, one or several oxygen, sulfur or nitrogen heteroatom and/or one or several groups chosen among —CO—, —CONH—, —COO—, —NHCO—, —N═N—, —S(O)—, —S(O)₂—, —P(═O)(ORa)—, with Ra being a C₁₋₈ alkyle.

For instance, L and L′ can be identical or different, and defined from the Si atom to Y by the structure -L1-L2- in which L1 is chosen among the following groups in their bivalent form: C₁₋₂₀ alkyl, C₁₋₂₀ alkenyl, C₁₋₂₀ alkynyl, C₆-C₂₄ aryl, C₇-C₄₄ alkylaryl, C₇-C₄₄ alkenylaryl, C₇-C₄₄ alkynylaryl, the said groups being able to contain triazole and tetrazole units and being unsubstituted or substituted with one or more moieties selected from C₁₋₁₀ alkoxy, C₁₋₁₀ alkyl, C₁₋₁₀ aryl, amido, imido, phosphido, nitrido, C₁₋₁₀ alkenyl, C₁₋₁₀ alkynyl, arene, phosphane, sulfonated phosphane, phosphate, phosphinite, arsine, ether, amine, amide, imine, sulfoxide, carboxyl, nitrosyl, pyridine, substituted pyridine, imidazole, substituted imidazole, triazole, tetrazole, pyrazine, substituted pyrazine and thioether; and L2 is chosen among —O—, —NH—, —N(C₁₋₆ alkyl)-, —N(benzyl)-, —N(phenyl)-, —C(O)—, —C(O)O—, —OC(O)—, —S—, —SO₂—, —N═N—, —NHC(O)— and —CONH—. For more details, see G. Parkin, Comprehensive Organometallic Chemistry III, Vol. 1, Chap. 1, Ed. Elsevier 2007.

The term used for the definition of the moieties have their usual meanings. In particular:

Alkyl is a saturated hydrocarbonated moiety which can be linear, branched or cyclic. Methyl, ethyl, cyclohexyl, ter-butyl are example of alkyl.

Aryl is an unsaturated mono or polycyclic hydrocarbonated moiety which includes at least an aromatic cycle. Example of aryl are phenyl and naphtyl groups.

Alrylalkyl is an unsaturated hydrocarbonated moiety which include at least an aryl part and an alkyl part. Benzyl is an example of arylalkyl.

Alkenyl is an unsaturated hydrocarbonated moiety which can be linear, branched or cyclic and which includes at least one double bond.

Alkynyl is an unsaturated hydrocarbonated moiety which can be linear, branched or cyclic and which includes at least one triple bond.

According to a first embodiment, m=1 and n=0 and, and as a result, the organic molecules which include at least one radical are located in the pores of the material.

According to a second embodiment, 2≦m+n and, and as a result, the organic molecules which include at least one radical are located in the walls of the material.

The materials according to the invention comprise organic molecules with unpaired electrons, named radicals in the present invention. These radicals will act as an electron source for DNP when the materials will be used in NMR analysis.

Advantageously, these radicals are persistent that means they are stable due to steric crowding around the radical center, which makes it physically difficult for the radical to react with another molecule. Examples of such persistent radicals include Gomberg's triphenylmethyl radical, Fremy's salt (Potassium nitrosodisulfonate, (KSO₃)₂NO.), nitroxides (general formula R2NO.) such as TEMPO, TEMPOL, nitronylnitroxides, and azephenylenyls and radicals derived from PTM (perchlorophenylmethyl radical) and TTM (tris(2,4,6-trichlorophenylmethyl radical).

So, whatever, the structure of the materials according to the invention, the radical(s) that is(are) present is (are) preferably a persistent radical. Such a radical can be chosen among nitroxyl, trityl and verdasyl radicals. For instance, the group Y in formula (I) can be a moiety of formula (A) bonded to one or several L/L′:

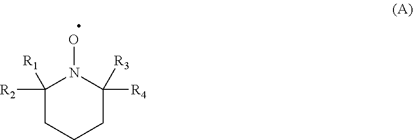

wherein R₁, R₂, R₃ and R₄, identical or different, are an alkyl (for instance with 1 to 10 carbon atoms) or aryl group (for instance with 6 to 12 carbon atoms), substituted or unsubstituted, or R₁ and R₂ and/or R₃ and R₄, as well as R₁ and R₃ and/or R₂ and R₄ are linked together thus forming a cycloalkyl, for instance with 5 to 12 carbon atoms, unsubstituted or substituted for instance with one or several phenyl. According to particular embodiments, R₁=R₂=R₃=R₄=methyl or R₁ and R₂, as well as R₃ and R₄, are linked together and form a cyclohexyl.

For instance, the organic-inorganic component (I) is chosen among:

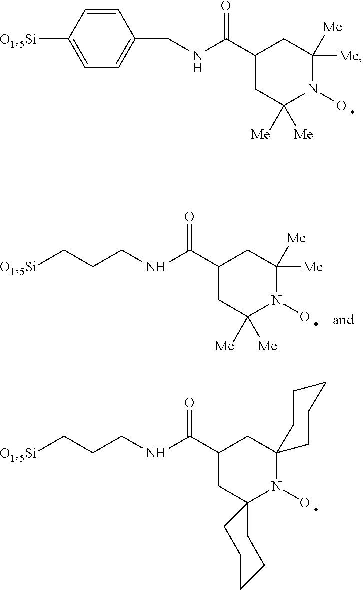

An example of materials according to the invention corresponds to a material of formula (III):

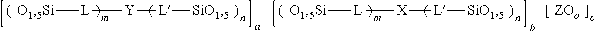

wherein
a, b and c can be identical or different and are integers selected as a>0, 0≦b/a≦1000, and 1≦(a+b+c)/(a+b)≦1000,
the Z atom is selected from silicon Si, zirconium Zr, titanium Ti, aluminium Al, and o is 2 when Z is Si, Zr or Ti and o is 1.5 when Z is Al and L, L′, X, Y, m and n are as defined for formula (I).

Advantageously, in the material according to the invention, the porous network is structured in an hexagonal array of the pores or in a cubic or wormlike arrangement of the pores.

The materials according to the invention are for instance in the form of a powder, which is compatible for their use as electron source for DNP or catalysis material, where they will be impregnated with a solution.

The materials according to the present invention are porous and structured materials.

An organized or structured material is necessary porous and is composed of pores and walls. The structuration corresponds to the long-range spatial ordering of the pores (cage like pores or pore-channels) into a network which can present several types of organization. Such organization can be analyzed by Small-Angle X-ray diffraction (XRD) and electron microscopy. The Small-Angle XRD is performed on a powder sample using the CuKα radiation (λ=0.154 nm). The diffraction patterns are usually collected in the 2Θ angle range [0.5°-10.0°], for instance at a scanning rate of 0.1°/min. A structured material can be defined as a material, which presents at least one peak on its Small-Angle XRD diffractogram. The peak(s) which can be visualized on the diffractogram is(are) characteristic of the presence of the porous organization into the analysed samples.

When just one peak, even broad, is obtained, the structuration of the porous network is considered as wormlike. When more than one diffraction peak is observed on the Small-Angle XRD diffractogram, the organisation of the porous network can be accurately determined and the interplane spacings, d(hkl) for different Miller indices (hkl) can be calculated using the Bragg's law (nk=2d sin Θ). So, it is possible to determine if the network has a hexagonal or a cubic organization, for instance.

When an hexagonal arrangement of the pore network is present in the sample, a minimum of three diffraction peaks corresponding to the interplane spacings with following Miller indices (1,0,0), (1,1,0), (2,0,0) are observed on the Small-Angle XRD diffractogram.

For cubic arrangements, several spaces groups can be observed by Small-Angle XRD depending of the diffraction peaks indexation:
With at least 3 peaks indexed as (1,1,0), (2,0,0) and (2,1,1) reflections, the cubic structure with Im3m space group is characterized,
With at least 3 peaks indexed as (1,1,1), (2,2,0) and (3,1,1) reflections, the cubic structure with Fm3m space group is characterized,
With at least 3 peaks indexed as (2,0,0), (2,1,0) and (2,1,1) reflections, the cubic structure with Pm3m space group is characterized.

The hexagonal, cubic or wormlike structure can also be confirmed easily by transmission electron microscopy. The obtained micrographs clearly show the long-range periodicity of the porous network.

The texture of the material and the porosity data on the material can be analysed by Dinitrogen adsorption and desorption measurements which are achieved at 77 K using specific apparatus. The specific surface area (S_{BET}) can be calculated by Brunauer-Emmett-Teller (BET) equation. The pore diameter distribution and the mean pore diameter can be calculated using Barrett-Joyner-Halenda (BJH) method from the adsorption branch of the N₂ adsorption-desorption isotherm.

Preferably, the materials according to the invention have a mean pore diameter from 2 nm to 50 nm, and more preferably from 3.5 nm to 50 nm. With such mean pore diameters and so at such a scale of organization, the material can be called mesostructured or mesoporous materials (Techniques de I'Ingénieur—Dossier texture des matériaux pulvérulents ou poreux, version of July 2012). As, the materials are structured, they present a narrow pore distribution. This narrow pore distribution is linked to the size of the structure directing agent used to structure the porous network and therefore to tune the size of the pores in the mesoporous range.

Such a mesoporous material with mean pore diameter from 3.5 nm to 50 nm (i.e. having a large pore volume) is particularly interesting, for DNP applications in particular, because such porosity allows the introduction of a larger volume of analyte solution (when compared to non-porous materials) and lead to greater enhancement. Moreover, the materials having large pores (more than 3.5 nm) are particularly interesting for introduction of complex—larger—analyte systems. The larger the pores are, the better it is (in the examples the pore diameters of the solids are around 6-8 nm). Materials which are either poorly porous or with little pores are therefore less interesting.

The range of dilutions defined as radical density (mmol radical·g⁻¹) selected according to the invention, with the regular distribution of the radicals obtained by the sol-gel process is particularly interesting for DNP application, because it minimizes the radical deactivation by quenching observed when radicals are very closed to each other when more important rates of radicals and/or grafting only in surface is used. The radical density can be simply obtained by using electron magnetic resonance spectroscopy (EPR), which allows the measurement of the number of electrons (radicals) per gram. The former can readily be obtained by placing the sample in powder form in a glass tube, and recording the EPR spectrum at room temperature (for instance 25° C.) at the X-band (9.52 GHz microwave frequency, conversion time=40.96 ms, time constant=5.12 ms, spectral widths=600 Gauss, and 1024 data points, modulation frequency=100 kHz, modulation amplitude=1 Gauss, and microwave power set to avoid saturation of the signal), integrating the EPR signals, which is proportional to the number of spins (radicals) and by comparing it with the integrated spectrum of a standard solution of any persistent radical such as TEMPO. The measure of the peak-to-peak EPR line width for the central peak of the CW spectra recording under the conditions described above, but at 110 K and with an impregnation of the material also allows evaluating the proximity of radicals and thus the homogeneity of the sample.

The materials according to the invention can be obtained by a sol-gel process using a templating route. That means that the sol-gel is performed with the use of at least one structure-directing agent, also named surfactant, to secure the formation of a porous network with i) the long range ordering of the pore periodicity and ii) the presence of calibrated pores with a narrow pore-size distribution. It is the reason why the obtained materials are called organized or structured materials.

A “sol-gel process” is a wet-chemical technique for the fabrication of materials (typically a metal oxide) starting from a chemical solution that reacts to produce colloidal particles (sol). Typical precursors are metal alkoxides and metal chlorides, which undergo hydrolysis and polycondensation reactions to form a colloid, a system composed of solid particles (size ranging from 1 nm to 1 μm) dispersed in a solvent. The sol progresses towards the formation of an inorganic network containing a liquid phase (gel). Formation of a metal oxide involves connecting the metal centers with oxo (M-O-M) or hydroxo (M-OH-M) bridges, therefore generating metal-oxo or metal-hydroxo polymers in solution. The drying process serves to remove the liquid phase from the gel thus forming a porous material, and then a thermal treatment (firing) may be performed in order to favor further polycondensation and enhance mechanical properties.

The classical sol-gel process and the synthesis of hybrid nanostructured materials by sol-gel process using a templating route have been respectively described by Corriu R. J. P et al. in Angew. Chem. Int; Ed. 1996, 35, 1420-1436 and in J. Mater. Chem 2005, 15, 4285. We can also refer to Dossier Techniques de I'Ingénieur, j5820 “Procédé sol-gel de polymerization” by P. Audebert and Miomandre, available version in July 2012. We can, for instance, refer to Ji Man Kim et al., J. Phys. Chem. B, 2002, 106, 2552-2558.

The materials according to the invention can be obtained by a sol-gel step with co-hydrolysis and co-condensation of an organosilane precursor that contains an organic group for yielding permanent radicals in the resulted materials and a silica or metal source in the form of tetraalkoxysilane, tetrahydroxysilane, alkoxymetal, hydroxymetal, alkoxyhydroxysilane, alkoxyhydroxymetal, silicate or metallate for instance. This silica or metal source can be defined by Z(OR″)ₓ, Z(OH)ₓ, Z(OR″)ₓ₁(OH)ₓ₂ or Z(O⁻)ₓ, (x/n)Eⁿ⁺ in which the value of x, x1 and x2 will depend of Z. For instance, when Z═Si, Ti or Zr, x=x1+x2=4 and when Z═Al, x=x1+x2=3. Eⁿ⁺ is a counter anion (from alkalin or alkalin earth column, Na⁺, Li⁺, K⁺ . . . ) and R″ is, for instance, a C₁₋₆ alkyl.

The organization of the porous network is obtained via the cooperative self-assembly of the inorganic and organic-inorganic precursors with a structure-directing agent.

Another object of the invention concerns a process for the preparation of a material according to the invention comprising the following steps:

a) a sol-gel step involving at least two precursors:
a tetraalkoxysilane, tetrahydroxysilane, alkoxymetal, hydroxymetal, alkoxyhydroxysilane, alkoxyhydroxymetal, silicate or metallate in which the metal is Zr, Ti or Al,
and an organosilane corresponding to a monosilyl or a polysilyl entity, for instance chosen among the organotrialkoxysilanes, organotrichlorosilanes, organotris(methallyl)silanes, organotrihydrogenosilanes, di-organosilane such as diorganodialkoxy or dichlorosilane, or disilyl compounds of general formula (Xa)₃Si—R′—Si(Xa)₃ with Xa=halogen, alkoxy, hydroxyl, methallyl or hydrogen, the selected organosilane carrying the organic moiety which includes at least one radical or carrying a reactive function allowing, in one or several additional step(s), the introduction of the organic molecules which include at least one radical,
   this sol-gel step being performed with a structure directing agent, for obtaining a porous and structured network,

b) when the step a) uses a trialkoxysilane carrying a reactive function, one or several additional step(s) are conducted for obtaining the covalent link of the organic molecules which include at least one radical on the inorganic network.

According to one embodiment, the step a) uses an organosilane carrying a reactive function selected from halogen atoms and functional groups such as azide, amine, amide, imine, nitrosyl, carboxyl, ketone, aldehyde, phosphine, phosphate, phosphinite, sulfoxide, —OH, —SH, and ether.

For instance, the step a) uses an organosilane carrying an azide function, which is further transformed in an NH₂ function, on which a reaction is carried with an organic molecule which includes at least one radical and a carboxyl group in order to form a NH—CO link.

According to one embodiment which can be combined to the previous ones, a further step is included after the step a) or b) which consists in removing the residual hydroxyl or alkoxy groups. This is typically done by reaction of the material with passivating agents, typically considered as hydrobobic and chosen among trialkylsilyl derivatives (chloro, bromo, iodo, amido or alkoxysilanes) or alcohols.

According to one embodiment which can be combined to the previous ones, a further step is included after the step a) or b) which consists in removing the structure directing agent. The structure directing agent can, for instance, be removed by washing with water or a proper polar solvent chosen among alcohols, amides, ethers and esters with/without the presence of an acid and/or a base, with or without a Soxhlet extraction. The structure-directing agent can also be removed by a Soxhlet extraction with aqueous HCl and pyridine.

According to one embodiment which can be combined to the previous ones, the step a) is achieved, with a structure directing agent, in water with or without at least one co-solvent, or in an appropriate polar solvent along with water, using hydrolysis-condensation catalysts chosen among bases, acids or nucleophilic compounds. For instance, the step a) is achieved, with a structure directing agent, in water with at least one co-solvent chosen among alcohols, amides, ethers, esters. Another possibility is to achieve the step a), with a structure directing agent, in a polar solvent chosen among alcohols, amides, ethers and esters.

For instance, the structure directing agent can be chosen among:

1) anionic surfactants (sodium dodecyl sulfate);
2) cationic surfactants: ammonium salts (cetyltrimethylammonium bromide), imidazolium salts (1-hexadecane-3-methylimidazolium bromide, pyridinium salts (n-hexadecylpyridinium chloride), phosphonium salts;
3) non-ionic surfactants:
amines (hexadecylamine (C₁₆H₃₃NH₂)),
alkylpolyethyleneoxides or alkylarylpolyethylene oxides (preferably C₁₆H₃₃O(CH₂CH₂O)₂H, C₁₁₋₁₅H₂₃₋₃₁O(CH₂CH₂O)₁₂H, C₁₄H₂₂O(C₂H₄O)ₙH, n=9-10), p-C₈H₁₇C₆H₄O(CH₂CH₂O)₁₀H, C₁₂H₂₅O(CH₂CH₂O)ₙH n˜2,4,8),
polysorbate surfactants (polyoxyethylene (20) sorbitan monolaurate) and,
amphiphilic block copolymers (preferably triblock copolymers such as EO₂₀-PO₇₀-EO₂₀, EO₁₀₀-PO₇₀-EO₁₀₀ or such as EO₁₃₂-PO₅₀-EO₁₃₂).

The concentration of surfactant used in the sol-gel step will depend on the surfactant nature and will be adjusted by the man skilled in the art. For instance, the typical concentration of some surfactants (i.e. the number of mole of surfactant per liquid solution volume and quoted [TA]) and the typical surfactant weight ratio (in %) i.e. Wt TA/Wt solution*100 (quoted TA/Sol), can be the following:
for cationic surfactants: 0.02<[TA]<2; 2%<TA/Sol<25%
for amine surfactants: 0.1<[TA]<0.8; 2%<TA/Sol<10%
for alkylpolyethyleneoxides or alkylarylpolyethylene oxides and polysorbate surfactants: 0.01<[TA]<2; 1%<TA/Sol<55%
for block copolymers: 0.001<[TA]<0.1; 2%<TA/Sol<55%.

In a preferred embodiment, the step a) is achieved with an hydrolysis polycondensation catalyst which is a base chosen among amines; or an acid chosen among inorganic acids such as hydrochloric acid, hydrobromic acid, iodidric acid . . . and organic acids such as p-toluene sulfonic acid; or a nucleophile such as sodium fluoride, tetrabutylammonium fluoride.

Materials according to the invention in which the organic molecules with at least one radical is bonded to only one Si which is part of the network, can, for instance, be prepared according to a process closed to the process used in the examples and detailed hereafter.

Such a process includes the following steps:

1^{st} step: synthesis of the mesostructured azido-containing materials,

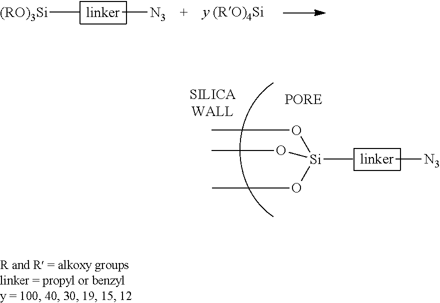

Y can be adapted and will influence the numbers of the radicals that will be present in the material after the third step.

These materials can be obtained by co-hydrolysis and co-condensation of tetraethylorthosilicate (TEOS) and 3-azidopropyltriethoxysilane in an aqueous HCl solution in presence of P123 as structure directing agent and NaF as catalyst for condensation. Of course, other structure directing agent and/or catalyst for condensation can be used.

The range of surface area for the obtained material at this stage is preferably in the range from 300 to 1000 m²/g.

2^{nd} step: in situ transformation of the azide group into amine,

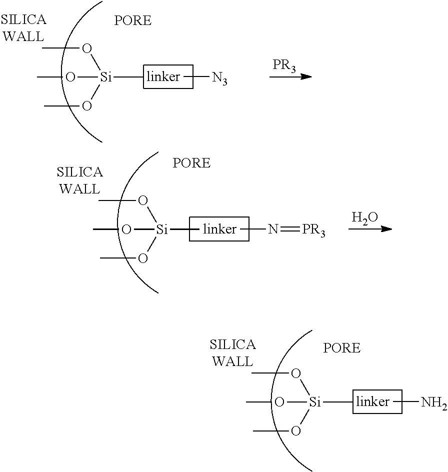

The reduction of azido-group to amino-unit is known as the Staudinger reaction (H. Staudinger; E. Hauser Helvetica Chimica Acta 1921, 4, 861-886.). It involves the formation of an intermediate iminophosphorane species, which can then be hydrolyzed to an amino group and phosphine oxide. For effective surface modification, the reaction is preferably carried out with a perfectly dry azide material and dry THF as solvent for the formation of the iminophosphorane. The reduction can be carried with dimethylphenylphosphine.

3rd step: introduction of -TEMPO radical via amidation reaction (reactivity between the amine of the solid and the carboxylic acid function of the 4-carboxy-TEMPO)

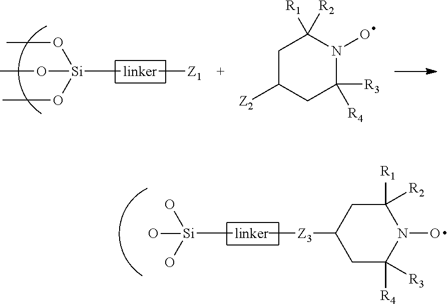

Z₁═NH₂, Z₂═COOH, Z₃═NHCO, and R₁, R₂, R₃ and R₄, identical or different, are an alkyl (for instance with 1 to 10 carbon atoms) or aryl group (for instance with 6 to 12 carbon atoms), substituted or unsubstituted, or R₁ and R₂ and/or R₃ and R₄, as well as R₁ and R₃ and/or R₂ and R₄ are linked together thus forming a cycloalkyl, for instance with 5 to 12 carbon atoms, unsubstituted or substituted, for instance with one or several phenyl.

A treatment between room temperature and 200° C., preferably at approximately 140° C. for instance, can be performed in some cases.

An analogous preparation process can be adopted in other cases, for instance with other linkers and/or other moieties including one or more radicals.

More generally, the first step can be carried with a silica or metal source of the type Z(OR)ₓ, Z(OH)ₓ, Z(OR)ₓ(OH)_{y} or Z(O⁻)ₓ, (x/n)Eⁿ⁺ previously defined for instance, and an organoalkoxysilane of formula (IV):

((RO)₃Si-Lₘ-XL′-Si(OR′)₃)ₙ (IV)

wherein X can be identical to Y as defined for the compounds (I) or can be a precursor of Y as a moiety substituted by at least one reactive function allowing, in one or several additional step(s), the introduction of at least one radical, L, L′, m and n are as defined for the compounds (I) and R and R′ are alkoxy groups, for instance C₁₋₆ alkoxy groups.

When, m=1 and n=0 and, the organoalkoxysilane is a monosilyl derivative and as a result, the organic molecules corresponding to -L-X will be located in the pores of the material.

According to another embodiment, 2≦m+n and, the organoalkoxysilane is a polysilyl derivative (for instance a bisilyl one) and as a result, the organic part corresponding to (L)m-X-(L′)n will located in the walls of the material.

The reactive function can, for instance, be selected from halogen atoms and functional groups such as azide, amine, amide, imine, nitrosyl, carboxyl, ketone, aldehyde, phosphine, phosphate, phosphinite, sulfoxide, —OH, —SH, and ether. The following steps will be adapted to the selected reactive function.

The material according to the invention can be used for catalysis reactions like oxidation reactions, as for example, oxidation of alcohols.

Nevertheless, the materials according to the invention are particularly suitable as polarization agents, in the Dynamic Nuclear Polarization (DNP) technique that enacts the transfer of electron spin polarization towards the core of a compound for which the Nuclear Magnetic Resonance (NMR) spectrum is observed. The particular structure of the materials according to the invention makes it possible to produce an optimal polarization transfer and an optimal increase in NMR signals for the polarized cores of the compound being studied. The polarization transfer can be obtained at a low temperature and high field.

Another object of the invention is related to a method of analysis by Nuclear Magnetic Resonance (NMR) of an analyte using dynamic nuclear polarization generated with a material according to the invention.

For instance, the analyte comprises any spin 1/2 nuclei such as ¹H, ¹³C, ³¹P, ¹⁵N, ²⁹Si and/or ¹⁹F atoms and/or quadrupolar nuclei such as ²⁷Al atoms which are analyzed.

The materials according to the invention can be used as a polarizing agent in the techniques of Nuclear Magnetic Resonance of solids or applied to liquid samples, using DNP. A material according to the invention can be used in a method of analysis by Nuclear Magnetic Resonance (NMR) of an analyte implementing dynamic nuclear polarization generated with a material to improve the detection of analytes (e.g., metabolites) that are present in a solution at low concentrations (e.g., less than 1 μm, less than 100 nM, less than 10 nM or even less than 1 nM.

According to a preferred embodiment the method comprises the following steps of:

x) A sample is prepared by mixing a solution of the analyte with the material according to the invention,
xx) The sample is polarized by microwave irradiation, the radical linked to the material allowing the generation of the polarization,
xxx) The NMR spectrum of the polarized analyte is recorded.

Advantageously, the whole sample is solidified before polarization and the polarization of the step xx) is performed on the solidified sample. In a preferred embodiment, the step xxx) is also performed on the solidified sample.

Both steps xx) and xxx) are preferably performed in an NMR spectrometer, especially when step xx) and/or step xxx) are/is performed on the solidified sample. This embodiment is easier to perform, but, of course, it is possible to perform the polarization outside the spectrometer.

The method can also be performed by solution NMR. For instance, the polarization can be made on the solidified sample but the NMR spectrum of the selected nucleus (i) of the polarized analyte recorded after dissolution of the solidified solution. Another possibility when solution NMR is used is to polarize the sample without solidification step directly on the sample containing the liquid solution of the analyte. In solution NMR method, advantageously, only step xxx) will be performed in an NMR spectrometer

According to another aspect, the invention also concerns a new solid state NMR method which corresponds to a method of analysis by NMR of one or several selected nuclei of an analyte of interest using dynamic nuclear polarization comprising the following steps of:

i) A sample is prepared by mixing a solution of the analyte with a material consisting in a porous network, this network being at least in part formed by inorganic oxide and such a material comprising organic molecules which include at least one radical and which are covalently bonded to the network by at least one siloxy bonds,
ii) The sample is solidified,
iii) The solidified sample is polarized by microwave irradiation, the radical linked to the material allowing the generation of polarization of the analyte,
iv) The NMR spectrum of the selected nucleus (i) of the polarized analyte is recorded on the solidified sample.

Advantageously, the network of the material used is structured and/or the network is formed with a sol-gel step using an organosilane for the introduction of the organic molecules allowing their regular distribution within the porous material. The organic molecules which include at least one radical and which are preferably covalently bonded to the network by two or three siloxy bonds.

In a preferred embodiment, the material used is a material according to the invention.

Advantageously, both steps iii) and iv) or steps ii) to iv) can be performed in an NMR spectrometer. These embodiments need less manipulation that can be advantageous, but, of course, it is possible to perform the solidification and/or the polarization outside the spectrometer.

The sample will be solidified, by placing the sample at a temperature which leads to the solidification of the analyte solution, for instance at a temperature in the range from 1K to 300 K and typically from 50 to 200 K.

Classically, the polarization is transferred from the unpaired electrons of the covalently linked radical to the nuclei of the analyte by the saturation of the electron transitions upon microwave irradiation.

Whatever the NMR technique and material used, before the analysis, the material used for DNP will be impregnated with a solution of analyte of interest. This solution can be made in water, glycerol or in any other solvent or combination of solvents, chosen for instance among those listed in the following reference, particularly toluene, chloroaromatics, chloroalkanes and bromoalkanes (Zagdoun et al. Chem. Commun. 2012, 48, 654-656). Before polarization, it is advantageous to obtain a mixture of the analyte solution and the materials as homogeneous as possible.

The analyte which can be studied by such methods comprises any spin 1/2 nuclei such as ¹H, ¹³C, ³¹P, ¹⁵N, ²⁹Si and/or ¹⁹F atoms and/or quadripolar nuclei such as ²⁷Al atoms which will be analyzed.

The following examples, in reference to the annexes Figures, illustrate the invention.

### A. Preparation and Characterization of Materials

### Characterization of Materials and Instrumentation

Transmission Electronic Microscopy.

Conventional TEM micrographs were performed at the “Centre Technologique des Microstructures”, UCBL, Villeurbanne, France, using a Philips 120 CX electron microscope. The acceleration voltage was 120 kV. The samples were prepared by dispersing a drop of the ethanol suspension of a ground sample on a Cu grid covered by a carbon film.

X-Ray Diffraction.

Small-Angle X-ray diffraction (XRD) on powder was carried out with a Bruker D8 Avance diffractometer (33 kV & 45 mA) with CuKα radiation (λ=0.154 nm) in the Service Diffraction RX, IRCE Lyon, France. The diffraction patterns were collected in the 2θ angle range [0.45°-7.0° ] at a scanning rate of 0.1°/min. The interplane spacings, d(hkl) for different Miller indices (hkl) were calculated using the Bragg's law (nk=2d sin θ). The lattice parameter (a0) for the hexagonal structured mesoporous material is given by a0=2d(100)/√3

Nitrogen Adsorption-Desorption Measurements.

The Nitrogen adsorption and desorption measurements were achieved at 77 K using a BELSORB-Mini from BEL-JAPAN. Before N₂ adsorption, the samples were outgassed at 10-4 Pa at 408 K for 12 h. The pore diameter distribution and the mean pore diameter (dp) were calculated using Barrett-Joyner-Halenda (BJH) method. The specific surface area (S_{BET}) was calculated by Brunauer-Emmett-Teller (BET) equation.

Electron Paramagnetic Resonance (EPR).

All spectra were recorded on an X-band Bruker EMX EPR spectrometer. Data analysis was performed using MatLab 2011 and Origin 8.5.

EPR spectra were recorded at X Band (9.52 GHz microwave frequency) with the following parameters: conversion time=40.96 ms, time constant=5.12 ms, modulation frequency=100 kHz, modulation amplitude=1 Gauss, spectral width=600 Gauss, and 1024 data points, microwave power adjusted to avoid saturation of the signal. The samples for line shape analysis were prepared as follows: dry TEMPO Material was wetted by incipient wetness impregnation with 1,1,2,2-Tetrachloroethane in air. The samples were filled in a 3.2 mm EPR quartz tube. The sample height in the tube was for all materials between 3 and 5 mm. EPR spectra were recorded at 110 K. The line width was determined using the CW spectra using the difference between the minimum and the maximum of the main signal (the central line), so called peak-to-peak linewidth. (Gerson, F.; Huber, W. In Electron Spin Resonance Spectroscopy of Organic Radicals; Wiley-VCH Verlag GmbH & Co. KGaA: 2004)

Samples for spin count experiments were prepared as follows: the dry powder was filled in a glass capillary (50 μL Hirschmann ring caps), and the bottom was closed with putty. The sample height was around 19 mm, and the weights were recorded for all samples. CW EPR spectra were recorded at room temperature. The quantification of the EPR signal was performed by using the double integral of the CW spectra corrected for microwave power, receiver gain and sample weight. Determination of the quantity of radical per gram was obtained by comparison to a standard TEMPO solution (4.07 mM in Toluene), and expressed in radical per surface area as evaluated from N2 adsorption measurement.

### EXAMPLE 1

### Mat-PrNHCO TEMPO with Different Dilutions—the Dilutions Given Hereafter Corresponds to the Theoretical Ratio Defined as the Amount of Organic Fragment in Mol Compared to the Total Amount of Si

### I. Preparation of Mat-PrN₃ with Different Dilutions

### Preparation of Mat-PrN₃ 1/11. Representative Procedure

P123 (9.19 g) dissolved in an aqueous HCl solution (365 mL, pH=1.5) was added in a mixture of tetraethoxysilane (TEOS, 20.5 mL, 91.7 mmol) and 3-azidopropyltrimethoxysilane (1.9 g, 9.3 mmol) at 25° C. The reaction mixture was stirred for 3 h giving rise to a micro-emulsion (transparent mixture). To the reaction mixture heated at 45° C., a small amount of NaF (127 mg, 3 mmol) was added under stirring (composition of the mixture: 12 TEOS: 1 of 3-azidopropyltriethoxysilane). The mixture was left at 45° C. under stirring for 72 h. The resulting solid was filtered, and washed three times with 100 mL of water and three times with 100 mL of acetone. The surfactant was removed by treatment in pyridine (30 mL), water (30 mL) and 2M HCl (5 mL) at 110° C. (reflux) for 20 h. After filtration, washing with water and ether, and drying at 135° C. under vacuum (10⁻⁵ mbar) for 12 h afforded Mat-PrN₃ 1/11 (5.60 g) as a white solid.

### Preparation of Mat-PrN₃ 1/17

Mat-PrN₃ 1/17 was prepared following the above-described procedure using 10.4 g of P123; aqueous HCl solution (415 mL, pH=1.5); TEOS (23.5 mL, 110 mmol); 3-azidopropyltrimethoxysilane (1.43 g, 7.0 mmol); NaF (200 mg, 4.7 mmol); Mat-PrN₃ 1/17 (8.5 g).

### Preparation of Mat-PrN₃ 1/20

Mat-PrN₃ 1/20 was prepared following the above-described procedure using 8.53 g of P123; aqueous HCl solution (340 mL, pH=1.5); TEOS (19.2 mL, 85.8 mmol); 3-azidopropyltrimethoxysilane (0.92 g, 4.48 mmol); NaF (161 mg, 3.8 mmol); Mat-PrN₃ 1/20 (6.2 g).

### Preparation of Mat-PrN₃ 1/26

Mat-PrN₃ 1/26 was prepared following the above-described procedure using 7.03 g of P123; aqueous HCl solution (281 mL, pH=1.5); TEOS (15.8 mL, 70.6 mmol); 3-azidopropyltrimethoxysilane (0.58 g, 2.83 mmol); NaF (176 mg, 4.2 mmol); Mat-PrN₃ 1/26 (3.5 g).

### Preparation of Mat-PrN₃ 1/35

Mat-PrN₃ 1/35 was prepared following the above-described procedure using 9.3 g of P123; aqueous HCl solution (365 mL, pH=1.5); TEOS (20.9 mL, 93.3 mmol); 3-azidopropyltriethoxysilane (0.57 g, 2.78 mmol); NaF (174 mg, 4.1 mmol); Mat-PrN₃ 1/35 (7.2 g).

### Preparation of Mat-PrN₃ 1/101

Mat-PrN₃ 1/101 was prepared following the above-described procedure using 9.5 g of P123; aqueous HCl solution (400 mL, pH=1.5); TEOS (21 mL, 96 mmol); 3-azidopropyltrimethoxysilane (0.20 g, 0.96 mmol); NaF (180 mg, 4.3 mmol); Mat-PrN₃ 1/101 (7.46 g).

### II. Preparation of Mat-PrNH₂ with Different Dilutions

### The Dilutions Given Hereafter Corresponds to the Theoretical Ratio Defined as the Amount of Organic Fragment in Mol Compared to the Total Amount of Si

### Preparation of Mat-PrNH₂ 1/11. Representative Procedure

PMe₂Ph (6 mL, 42 mmol) in solution in 50 mL of dry THF was added to 5.25 g of material Mat-PrN₃ 1/11. After stirring for 24 h at room temperature, the suspension was filtered, and the product washed with THF. The resulting material was dispersed in a mixture of 10 mL water and 50 mL THF, and stirred for an additional 17 h. It was then filtered, washed 3 times with 100 mL of acetone and three times with 100 mL of methanol. The remaining phosphine oxide was removed by an extraction with methanol using a Soxhlet during 48 h. After filtration, washing with methanol and ether, and drying at 135° C. under vacuum (10⁻⁵ mbar) for 12 h, Mat-PrNH₂ 1/13 (4.76 g) was obtained as a white solid.

### Preparation of Mat-PrNH₂ 1/17

Mat-PrNH₂ 1/16 was prepared following the above-described procedure using PMe₂Ph (6.6 mL, 46 mmol); THF (100 mL); Mat-PrN₃ 1/16 (6 g); Mat-PrNH₂ 1/16 (5 g).

### Preparation of Mat-PrNH₂ 1/20

Mat-PrNH₂ 1/20 was prepared following the above-described procedure using PMe₂Ph (5 mL, 34.5 mmol); THF (50 mL); Mat-PrN₃ 1/20 (5.2 g); Mat-PrNH₂ 1/20 (5 g).

### Preparation of Mat-PrNH₂ 1/26

Mat-PrNH₂ 1/26 was prepared following the above-described procedure using PMe₂Ph (4 mL, 27.6 mmol); THF (50 mL); Mat-PrN₃ 1/31 (5.25 g); Mat-PrNH₂ 1/26 (5.05 g).

### Preparation of Mat-PrNH₂ 1/35

Mat-PrNH₂ 1/35 was prepared following the above-described procedure using PMe₂Ph (3 mL, 20.7 mmol); THF (50 mL); Mat-PrN₃ 1/41 (5.25 g); Mat-PrNH₂ 1/35 (5.10 g).

### Preparation of Mat-PrNH₂ 1/101

Mat-PrNH₂ 1/101 was prepared following the above-described procedure using PMe₂Ph (0.38 mL, 2.6 mmol); THF (20 mL); Mat-PrN₃ 1/101 (1.59 g); Mat-PrNH₂ 1/101 (1.22 g).

### III. Preparation of Mat-PrNHCO-TEMPO with Different Dilutions

### The Dilutions Given Hereafter Corresponds to the Theoretical Ratio Defined as the Amount of Organic Fragment in Mol Compared to the Total Amount of Si

### Preparation of Mat-PrNHCO-TEMPO 1/11. Representative Procedure

O-Benzotriazole-N,N,N′,N′-tetramethyl-uronium-hexafluoro-phosphate (HBTU, 892 mg, 2.35 mmol, 1.3 equiv.), N-hydroxybenzotriazole (HOBt, 377 mg, 2.46 mmol, 1.4 equiv.), diisopropylethylamine (DIEA, 1.3 mL, 7.51 mmol, 4.1 equiv.) and 4-carboxy-TEMPO (471 mg, 2.35 mmol, 1.3 equiv.) dissolved in 24 mL of a mixture of THF/DMF (50/50) was added to a suspension of Mat-PrNH₂ 1/11 (2.2 g, 1 equiv.) in 48 mL of THF. After stirring at room temperature for 12 h, the resulting material was filtered, washed with THF (3×100 mL), toluene (3×100 mL), pentane (3×100 mL) and ether (3×100 mL). After drying at 135° C. under vacuum (10⁻⁵ mbar) for 12 h, Mat-PrNHCO-TEMPO 1/11 (1.89 g) was obtained as a light tan solid.

### Preparation of Mat-PrNHCO-TEMPO 1/17

Mat-PrNHCO-TEMPO 1/17 was prepared following the above-described procedure using HBTU (100 mg, 0.26 mmol); HOBt (40 mg, 0.26 mmol); DIEA (0.1 mL, 0.58 mmol); 4-carboxy-TEMPO (52 mg, 0.26 mmol); THF/DMF (50/50) (7 mL/7 mL); Mat-PrNH₂ 1/17 (400 mg); THF (7 mL); Mat-Pr-TEMPO 1/17 (350 mg).

### Preparation of Mat-PrNHCO-TEMPO 1/20

Mat-PrNHCO-TEMPO 1/20 was prepared following the above-described procedure using HBTU (130 mg, 0.34 mmol); HOBt (47 mg, 0.31 mmol); DIEA (0.17 mL, 0.98 mmol); 4-carboxy-TEMPO (61 mg, 0.30 mmol); THF/DMF (50/50) (6 mL/6 mL); Mat-PrNH₂ 1/20 (450 mg); THF (6 mL); Mat-PrNHCO-TEMPO 1/20 (320 mg).

### Preparation of Mat-PrNHCO-TEMPO 1/26

Mat-PrNHCO-TEMPO 1/26 was prepared following the above-described procedure using HBTU (173 mg, 0.46 mmol); HOBt (63 mg, 0.41 mmol); DIEA (1.3 mL, 7.51 mmol); 4-carboxy-TEMPO (86 mg, 0.43 mmol); THF/DMF (50/50) (12 mL/12 mL); Mat-PrNH₂ 1/26 (800 mg); THF (10 mL); Mat-PrNHCO-TEMPO 1/26 (800 mg).

### Preparation of Mat-PrNHCO-TEMPO 1/35

Mat-PrNHCO-TEMPO 1/35 was prepared following the above-described procedure using HBTU (134 mg, 0.35 mmol); HOBt (51 mg, 0.33 mmol); DIEA (1 mL, 5.78 mmol); 4-carboxy-TEMPO (66 mg, 0.33 mmol); THF/DMF (50/50) (10 mL/10 mL); Mat-PrNH₂ 1/35 (1 g); THF (10 mL); Mat-PrNHCO-TEMPO 1/35 (879 mg).

### Preparation of Mat-PrNHCO-TEMPO 1/101

Mat-PrNHCO-TEMPO 1/101 was prepared following the above-described procedure using HBTU (42 mg, 0.11 mmol); HOBt (22 mg, 0.14 mmol); DIEA (0.05 mL, 0.29 mmol); 4-carboxy-TEMPO (20 mg, 0.10 mmol); THF/DMF (50/50) (12 mL/12 mL); Mat-PrNH₂ 1/101 (465 mg); THF (40 mL); Mat-PrNHCO-TEMPO 1/101 (385 mg).

Textural characteristics of the materials

| | Surface | Pore | Mean pore |
|---|---|---|---|
| | Area | volume | diameter dₚ |
| Materials | (m²/g) | (cm³/g) | (nm) |
| Mat-PrN₃ 1/11 | 940 | 1.13 | 5.41 |
| Mat-PrN₃ 1/17 | 655 | 1.07 | 7.95 |
| Mat-PrN₃ 1/20 | 1050 | 0.91 | 7.05 |
| Mat-PrN₃ 1/26 | 730 | 0.78 | 7.05 |
| Mat-PrN₃ 1/35 | 860 | 1.35 | 9.23 |
| Mat-PrN₃ 1/101 | 706 | 1.41 | 7.97 |
| Mat-PrNH₂ 1/11 | 630 | 0.95 | 6.18 |
| Mat-PrNH₂ 1/17 | 553 | 0.89 | 7.05 |
| Mat-PrNH₂ 1/20 | 660 | 0.75 | 7.05 |
| Mat-PrNH₂ 1/26 | 710 | 1.54 | 7.05 |
| Mat-PrNH₂ 1/35 | 880 | 0.90 | 9.23 |
| Mat-PrNH₂ 1/101 | 723 | 1.31 | 7.24 |
| Mat-PrNHCO-TEMPO 1/11 | 540 | 1.54 | 6.18 |
| Mat-PrNHCO-TEMPO 1/17 | 480 | 0.80 | 7.0 |
| Mat-PrNHCO-TEMPO 1/20 | 650 | 0.78 | 6.18 |
| Mat-PrNHCO-TEMPO 1/26 | 590 | 0.77 | 7.05 |
| Mat-PrNHCO-TEMPO 1/35 | 630 | 1.10 | 9.23 |
| Mat-PrNHCO-TEMPO 1/101 | 723 | 1.48 | 8.18 |

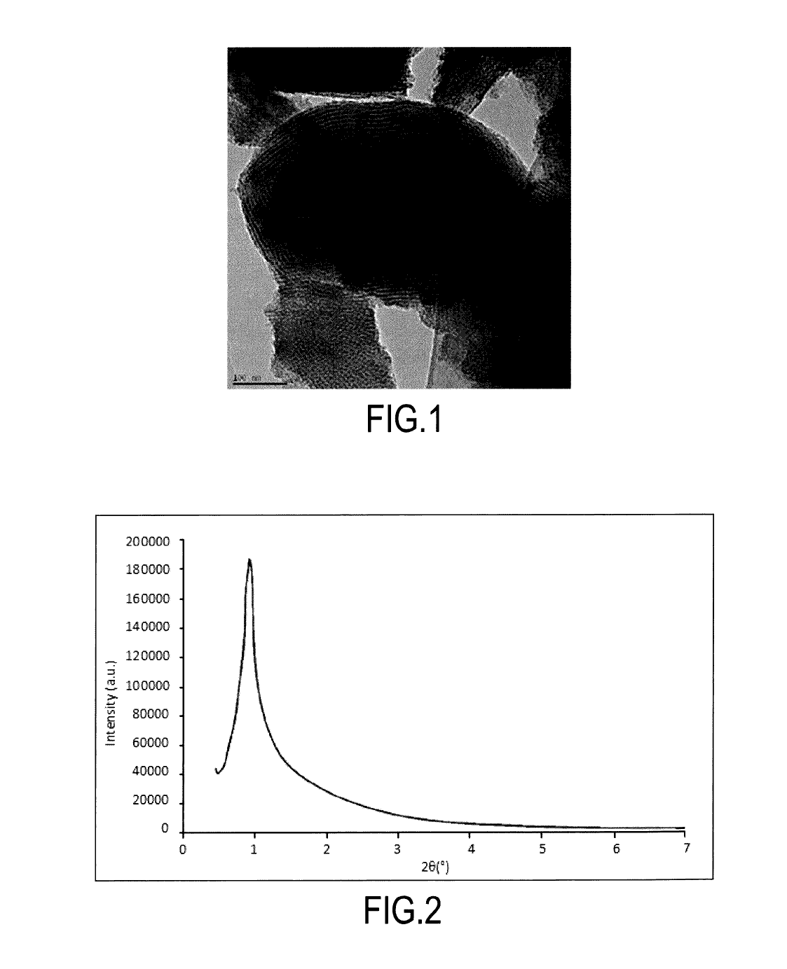

FIG. 1 shows a TEM picture of Mat-PrNHCO-TEMPO 1/11.

Small Angle XRD pattern of the material Mat-PrNHCO-TEMPO 1/11 is presented FIG. 2.

The following values are obtained: d(100)=9.4 nm (2Θ=0.93°) and a0=13.1 nm

Both TEM picture and small angle XRD diffractogram indicate that Mat-PrNHCO-TEMPO 1/11 displays a wormlike structure.

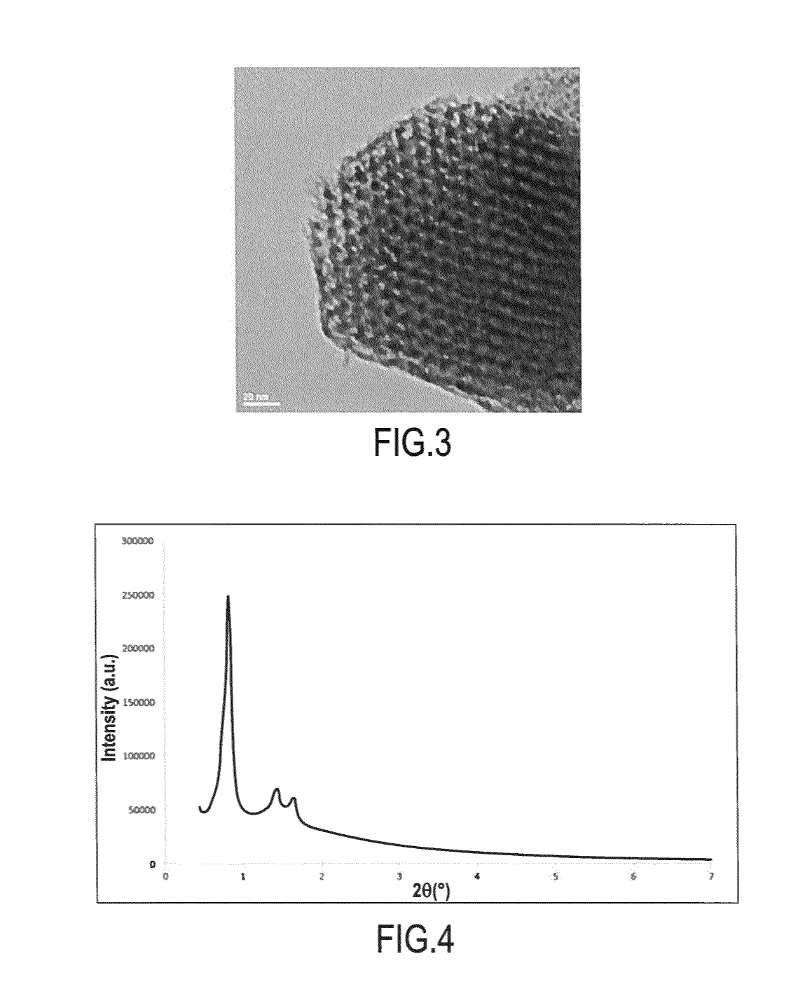

FIG. 3 shows a TEM picture of Mat-PrNHCO-TEMPO 1/101.

Small Angle XRD pattern of the material Mat-PrNHCO-TEMPO 1/101 is presented FIG. 4.

The following values are obtained: d(1,0,0)=10.5 nm (2Θ=0.83°), d(1,1,0)=6.3 nm (2Θ=1.41°), d(2,0,0)=5.5 (2Θ=1.62°) and a0=14.6 nm.

Both TEM picture and small angle XRD diffractogram indicate that Mat-PrNHCO-TEMPO 1/101 displays a hexagonal structure.

| | Structure from |
|---|---|
| Materials | XRD and/or TEM |
| Mat-PrNHCO-TEMPO 1/11 | wormlike |
| Mat-PrNHCO-TEMPO 1/17 | wormlike |
| Mat-PrNHCO-TEMPO 1/20 | wormlike |
| Mat-PrNHCO-TEMPO 1/26 | wormlike |
| Mat-PrNHCO-TEMPO 1/35 | hexagonal |
| Mat-PrNHCO-TEMPO 1/101 | hexagonal |

EPR characteristics of the materials.

| | Density of | Measurement |
|---|---|---|
| | radical mea- | of radical |
| | sured at RT | distribution |
| | mmol | EPR line |
| Material | Radical · g⁻¹ | width/Gauss |
| Mat-PrNHCO-TEMPO 1/11 | 0.277 | 22.0 |
| Mat-PrNHCO-TEMPO 1/17 | 0.262 | 17.6 |
| Mat-PrNHCO-TEMPO 1/20 | 0.156 | 15.3 |
| Mat-PrNHCO-TEMPO 1/26 | 0.138 | 14.7 |
| Mat-PrNHCO-TEMPO 1/35 | 0.099 | 11.7 |
| Mat-PrNHCO-TEMPO 1/101 | 0.038 | 11.7 |

### EXAMPLE 2

### Mat-PrNHCO-Cyclohexyl TEMPO 1/35 which Corresponds to the Theoretical Ratio Defined as the Amount of Organic Fragment in Mol Compared to the Total Amount of Si

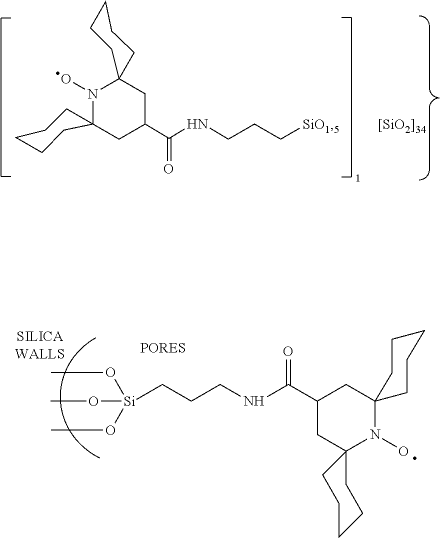

### Representative Procedure.

Mat-PrNHCO-cyclohexylTEMPO 1/35 was prepared following the above-described procedure using HBTU (79 mg, 0.21 mmol); HOBt (30 mg, 0.20 mmol); DIEA (0.11 mL, 0.64 mmol); 4-carboxy-cyclohexylTEMPO (58 mg, 0.21 mmol); THF/DMF (50/50) (12 mL/12 mL); Mat-PrNH₂ 1/35 (401 mg); THF (40 mL); Mat-PrNHCO-cyclohexylTEMPO 1/35 (352 mg). Surface area=640 m²·g⁻¹; Pore Volume=1.10 cm³·g⁻¹; Mean Pore diameter=9.2 nm from N₂ adsorption measurement. Hexagonal arrangement from XR-D.

| | Density of | Measurement |
|---|---|---|
| | radical mea- | of radical |
| | sured at RT | distribution |
| | mmol | EPR line |
| Material | Radical · g⁻¹ | width/Gauss |
| Mat-PrNHCO- | 0.066 | 14.1 |
| cyclohexylTEMPO 1/35 | | |

### EXAMPLE 3

### Mat-BzNHCO-TEMPO 1/31 Corresponds to the Theoretical Ratio Defined as the Amount of of Organic Fragment in Mol Compared to the Total Amount of Si

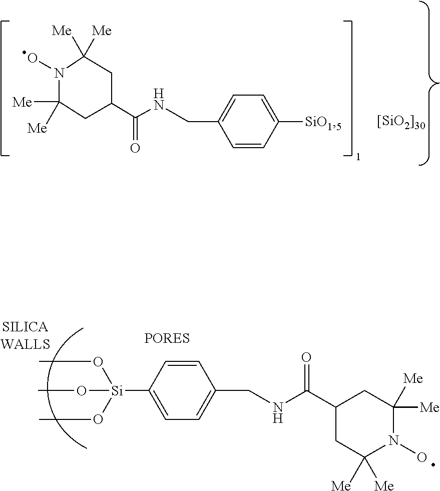

| | Density of | Measurement |
|---|---|---|
| | radical mea- | of radical |
| | sured at RT | distribution |
| | mmol | EPR line |
| Material | Radical · g⁻¹ | width/Gauss |
| Mat-BzNHCO-TEMPO 1/31 | 0.147 | 12.3 |

### I. Preparation of Mat-BzN₃ 1/31. Representative Procedure

Mat-BzN₃ 1/31 was prepared following the procedure described for Mat-PrN₃ 1/11 using 6.8 g of P123; aqueous HCl solution (272 mL, pH=1.5); TEOS (15.3 mL, 68.4 mmol); 3-azidobenzyltrimethoxysilane (0.58 g, 2.28 mmol); NaF (133 mg, 3.1 mmol); Mat-BzN₃ 1/31 (3.42 g).

Characteristics of the materials:

| | | Surface | Pore | Mean pore |
|---|---|---|---|---|
| Materials | | Area | volume | diameter dₚ |
| | Dilution | (m²/g) | (cm³/g) | (nm) |
| Mat-PrN₃ | 1/31 | 1000 | 1.2 | 5.0 |

### II. Preparation of Mat-BzNH₂ 1/31

Mat-BzNH₂ 1/31 was prepared following the procedure described for Mat-PrNH₂ 1/11 using PMe₂Ph (1.9 mL, 13.1 mmol); THF (30 mL); Mat-BzN₃ 1/31 (3.1 g); Mat-BzNH₂ 1/31 (0.90 g).

### III. Preparation of Mat-BzNHCO-TEMPO 1/31

Mat-BzNHCO-TEMPO 1/31 was prepared following the procedure described for Mat-PrNHCO-TEMPO 1/11 using HBTU (65 mg, 0.17 mmol); HOBt (26 mg, 0.17 mmol); DIEA (0.1 mL, 0.58 mmol); 4-carboxy-TEMPO (35 mg, 0.17 mmol); THF/DMF (50/50) (8 mL/8 mL); Mat-BzNH₂ 1/31 (399 mg); THF (4 mL); Mat-BzNHCO-TEMPO 1/31 (340 mg). Hexagonal structure from XRD.

### EXAMPLE 4

### Mat-PrNHCO-Trityle 1/35 Corresponds to the Theoretical Ratio Defined as the Amount of of Organic Fragment in Mol Compared to the Total Amount of Si

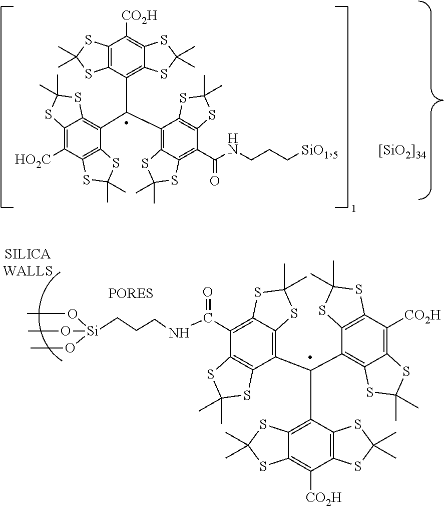

O-Benzotriazole-N,N,N′,N′-tetramethyl-uronium-hexafluoro-phosphate (HBTU, 67 mg, 0.18 mmol, 1.3 equiv.), N-hydroxybenzotriazole (HOBt, 31 mg, 0.20 mmol, 1.5 equiv), ethyldiisopropylamine (DIEA, 0.1 mL, 0.54 mmol, equiv) and the Tris(8-carboxy-2,2,6,6-tetramethylbenzo-[1,2-d; 4,5-d]bis[1,3]dithiol-4-yl)methyl (272 mg, 0.27 mmol, 2 equiv) dissolved in a 10 mL of a mixture of THF/DMF (75/25) was added to a suspension of Mat-PrNH2 1/35 (300 mg, 1 equiv.) in 10 mL of THF. After stirring at room temperature for 24 h, the resulting material was filtered with THF, (3×20 mL), toluene (3×20 mL) and ether (3×20 mL). After drying at 135° C. under vacuum (10⁻⁵ mbar), Mat-PrNHCO-Trit. 1/35 (240 mg) was obtained as a yellowish powder.

Structuration and texture of the material

| | | Texture | | |
|---|---|---|---|---|
| | | Pore | Surface | Mean pore |
| | | volume | area | diameter |
| Materials | Structuration | (cm³/g) | (m²/g) | (nm) |
| Mat-PrNHCO- | hexagonal | 1.2 | 684 | 9.2 |
| Trit. 1/35 | | | | |

EPR characteristics of the materials.

| | Density of | Measurement |
|---|---|---|
| | radical mea- | of radical |
| | sured at RT | distribution |
| | mmol | EPR line |
| Material | Radical · g⁻¹ | width/Gauss |
| Mat-PrNHCO-Trit. 1/35 | 0.011 | 2.1 |

### B. NMR Experiments

### Sample Preparation for NMR Experiments

Samples were prepared by incipient wetness impregnation (see the movie http://pubs.acs.org/JACSbeta/scivee/index.html#video2) using 8.5-16.2 mg of dry powder with 20-30 4 of an analyte containing solution or with pure solvent (H₂O or 1,1,2,2-tetrachloroethane, EtCl₄). The total mass of impregnated material was determined, and the sample was mixed using a glass-stirring rod to obtain a homogeneous distribution of the radical containing solution in the powder. The impregnated powder was then packed into a 3.2 mm sapphire NMR rotor to maximize MW penetration into the sample. The mass of impregnated material inside the rotor was determined, and a tight polyfluoroethylene plug was inserted to prevent any leakage of the solvent during spinning. The rotor was capped with a zirconia drive tip and quickly inserted into the DNP spectrometer.

Solid-State NMR Spectroscopy.

All spectra were acquired on a Bruker Avance III 400 MHz DNP NMR spectrometer equipped with a 263 GHz gyrotron microwave system (B₀=9.4 T, ω_{H}/2π=400 MHz, ω_{C}/2π=100 MHz, ω_{Si}/2π=79.5 MHz). The field sweep coil of the NMR magnet was set so that MW irradiation occurred at the DNP enhancement maximum of TOTAPOL (263.334 GHz), with an estimated 4 W power of the MW beam at the output of the probe waveguide. ¹H, ¹³C, and ²⁹Si spectra were recorded using a triple resonance low-temperature CPMAS probe with a sample temperature of 99 K and sample spinning frequencies of 12 kHz for the ¹³C spectra and 8 kHz for the ²⁹5 i spectra. SPINAL-6438 heteronuclear decoupling was applied during acquisition (ω_{1H}/2π=100 kHz). ¹H, ¹³C and ²⁹Si chemical shifts are referenced to TMS at 0 ppm.

Standard cross-polarization (CP) was used for 1D carbon-13 and silicon-29 spectra. For ¹³C CPMAS The ¹H π/2 pulse length was 2.5 μs (100 kHz). A linear amplitude ramp (from 50% to 100% of the nominal RF field strength) was used for the ¹H channel, with a 3.0 ms contact time and a nominal RF field amplitude of ν₁=68 kHz for ¹H and 50 kHz for ¹³C. SPINAL-64 proton decoupling was applied during the acquisition of the ¹³C signal with an RF field amplitude of ν₁=100 kHz. The ¹³C acquisition time was 10 ms with 992 complex points.

For ²⁹Si CPMAS The ¹H π/2 pulse length was 2.5 μs (100 kHz). A linear amplitude ramp (from 50% to 100% of the nominal RF field strength) was used for the ¹H channel, with a 2.0 ms contact time and a nominal RF field amplitude of ν₁=65 kHz for ¹H and 50 kHz for ²⁹Si. SPINAL-64 proton decoupling was applied during the acquisition of the ²⁹Si signal with an RF field amplitude of ν₁=100 kHz. The ²⁹Si acquisition time was 10 ms with 992 complex points.

Spectra were acquired with 32-512 scans for ¹³C and 32-1024 scans for ²⁹5 i in order to obtain a good signal on noise ratio.

Processing of the spectra was done using the Topspin software package.

DNP Enhancement Factors Calculation.

DNP enhancement factors on the nucleus X (ε_{X}) were determined by scaling the intensities of the spectra of the nuclei X obtained under the same experimental conditions with or without MW irradiation.

NMR Enhancements

| | Radical | | Enhancement | | |
|---|---|---|---|---|---|
| | conc. | | Surface | Bulk | |
| Material | (mmol · g⁻¹) | Solvent | ²⁹Si | ¹³C | ¹H |
| PrNHCO-TEMPO 1/101 | 0.038 | H₂O | 30.4 | — | 23.2 |
| PrNHCO-TEMPO 1/35 | 0.099 | H₂O | 36.0 | — | 21.8 |
| PrNHCO-TEMPO 1/26 | 0.138 | H₂O | 36.3 | — | 17.4 |
| PrNHCO-TEMPO 1/20 | 0.156 | H₂O | 30.4 | — | 11.7 |
| PrNHCO-TEMPO 1/17 | 0.262 | H₂O | 5.4 | — | 2.0 |
| PrNHCO-TEMPO 1/11 | 0.277 | H₂O | X | — | 3.9 |
| PrNHCO-TEMPO 1/101 | 0.038 | EtCl₄ | 8.6 | 8.3 | 8.1 |
| PrNHCO-TEMPO 1/35 | 0.099 | EtCl₄ | 15.8 | 21.2 | 21.4 |
| PrNHCO-TEMPO 1/26 | 0.138 | EtCl₄ | 10.8 | 15.4 | 14.1 |
| PrNHCO-TEMPO 1/20 | 0.156 | EtCl₄ | 7.4 | 9.8 | 11.9 |
| PrNHCO-TEMPO 1/17 | 0.262 | EtCl₄ | X | 9.6 | 9.4 |
| PrNHCO-TEMPO 1/11 | 0.277 | EtCl₄ | X | 5.5 | 6.6 |
| PrNHCO- | 0.066 | H₂O | 38.2 | — | 24.8 |
| cyclohexylTEMPO 1/35 | | | | | |
| PrNHCO- | 0.066 | EtCl₄ | 25.8 | 23.8 | 25.8 |
| cyclohexylTEMPO 1/35 | | | | | |
| BzNHCO-TEMPO 1/31 | 0.147 | H₂O | 28.2 | — | 11.7 |
| BzNHCO-TEMPO 1/31 | 0.147 | EtCl₄ | 7.4 | 9.7 | 12.1 |

“—” means that the measurement was not feasible
“X” means that no enhancement was observed

The control of the distribution, the loading of the radicals within the materials and the pore size as obtained by sol-gel using a templating route is particularly interesting for DNP application, as far as a regular distribution of the radical and a control of its loading will prohibit the radical deactivation by quenching (observed when radicals are very closed to each other) and as far as enough radicals are present to enhance the NMR signal. In order to have an optimum, the materials should contain enough, but not too much radicals and therefore a balance in dilution is important. As observed in the examples, PrNHCO-TEMPO 1/11 with radical concentration of 0.277 mmol·g⁻¹ allows an inferior NMR signal enhancement, an optimum is observed for concentration of 0.06-0.25 mmol·g⁻¹ of radicals and the enhancement starts decreasing for concentration below 0.06 mmol·g⁻¹ (as exemplified by PrNHCO-TEMPO 1/101). The inventors have also prepared more diluted materials (dilution inferior to 0.03 mmol·g⁻¹) which lead to very low enhancement, judged unsatisfied and not presented.

These results also suggest that radical doped materials obtained by grafting of radicals onto oxide supports would be less efficient as it is very difficult to have a homogeneous distribution of the radical on the oxide surface (for porous materials, most of the organic groups are present in the entrance of the pores and are closed to each other).

In fact, with the materials with important amount of radicals, the EPR technique shows that the radicals are closed to each other and the NMR enhancement is low compared to more diluted systems, and this would certainly be worth for grafted systems.

### COMPARATIVE EXAMPLE

Using commercially available porous, but non-structured TEMPO supported silica based solid (SiliaCAT® TEMPO used by Lafon et al. in Applied Magn. Reson. 2012, 43, 237), incipient wetness impregnation, using 48-60 mg of the dry powder with 40-60 μL of solvent, H₂O or EtCl₄ gave the following enhancements: in H2O, ε_{H}=1.4 and ε . . . <1.1 and in EtCl₄, ε_{H}=3.5, ε_{C}=1.9 and ε . . . <1.1.

This shows the advantages of using a porous material and, in particular an organized material according to the invention.

1. Material in a porous and structured network being at least in part formed by Si atoms, or Si atoms and metal atoms, linked to each other's by oxy bridges, characterized in that the material comprises organic molecules which include at least one radical and which are covalently bonded to the network via siloxy bonds, the amount of radicals ranging from 0.50 to 0.03 mmol of radical per gram of material, and in that the network is formed with a sol-gel step using an organosilane for the introduction of the organic molecules allowing their regular distribution within the porous structured material.

2. A material according to claim 1, characterized in that its mean pore diameter belongs to the range from 35 Å to 500 Å.

3. A material according to claim 1 characterized in that the organic molecules which include at least one radical are located in the mass of the material, and can be localized:
either in the pores of the material and in this case the network is only formed by Si atoms, or Si atoms and metal atoms, linked to each other's by oxy bridges, or
in the walls of the material and in that case the network is formed by inorganic oxide and the organic molecules.

4. A material according to claim 1 characterized in that the network or its inorganic part is made of silica SiO₂, alumina Al₂O₃, TiO₂ or ZrO₂.

5. A material according to claim 1 characterized in that it is obtainable by a sol-gel method involving at least two precursors:
a tetraalkoxysilane, tetrahydroxysilane, alkoxymetal, hydroxymetal, alkoxyhydroxysilane, alkoxyhydroxymetal, silicate or metallate in which the metal is Zr, Ti or Al,
and an organosilane corresponding to a monosilyl or a polysilyl entity, for instance chosen among the organotrialkoxysilanes, organotrichlorosilanes, organotris(methallyl)silanes, organotrihydrogenosilanes, di-organosilane such as diorganodialkoxy or dichlorosilane, or disilyl compounds of general formula X₃Si—R′—SiX₃ with X=halogen, alkoxy, hydroxyl, methallyl or hydrogen, the selected organosilane carrying the organic moiety which includes at least one radical or carrying a reactive function allowing, in one or several additional step(s), the introduction of the organic molecules which include at least one radical.

6. A material according to claim 1 characterized in that the organosilane used for the introduction of the organic molecule which includes at least one radical, is carrying a reactive function selected from halogen atoms and functional groups such as azide, amine, amide, imine, nitrosyl, carboxyl, ketone, aldehyde, phosphine, phosphate, phosphinite, sulfoxide, —OH, —SH, and ether.

7. A material according to claim 1, characterized in that the sol-gel step is performed with a structure-directing agent.

8. A material according to claim 7 characterized in that the material obtained by the sol-gel method is treated to remove the structure directing agent, before the step(s) carried for linking the organic molecule which includes at least one radical by reaction on the reactive function.

9. A material according to claim 7 characterized in that the sol-gel method is achieved, with a structure directing agent, in water with or without at least one co-solvent or in an appropriate polar solvent along with water, using hydrolysis-condensation catalysts chosen among bases, acids or nucleophilic compounds.

10. A material according to claim 7 characterized in that the sol-gel method is achieved, with a structure directing agent chosen among:
alkylpolyethyleneoxides or alkylarylpolyethylene oxides (preferably C₂₆H₃₃O(CH₂CH₂O)₂H, C₁₁₋₁₅ H₂₃₋₃₁O(CH₂CH₂O)₁₂H, C₁₄H₂₂O(C₂H₄O)ₙH, n=9-10), p-C₈H₁₇C₆H₄O(CH₂CH₂O)₁₀H, C₁₂H₂₅O(CH₂CH₂O)ₙH n˜2,4,8),
polysorbate surfactants (polyoxyethylene (20) sorbitan monolaurate) and,
amphiphilic block copolymers (preferably triblock copolymers such as EO₂₀-PO₇₀-EO₂₀, EO₁₀₀-PO₇₀-EO₁₀₀ or such as EO₁₃₂-PO₅₀-EO₁₃₂).

11. A material according to claim 1 characterized in that the ratio (numbers of radical)/(total number of Si atoms and metal atoms when they are present) preferably belongs to the range from 1/27 to 1/500.

12. A material according to claim 1 characterized in that it comprises at least one organic-inorganic component (I) distributed within its porous silica network of formula (I):
(O_{1,5}Si-LₘYL′-SiO_{1,5})ₙ (I)
wherein
Y is a moiety which includes at least one radical,
L and L′ can be identical or different and are connecting organic moiety,
n and m can be identical or different and are integers selected as 1≦m+n<5,
the SiO_{1,5} are part of the inorganic part of the network.

13. A material according to claim 12 characterized in that it comprises at least one organic-inorganic component (II) distributed within its porous silica network of formula (II):
(O_{1,5}Si-LₘXL′-SiO_{1,5})ₙ (II)
wherein
X is a moiety including at least one reactive function allowing, in one or several additional step(s), the introduction of at least one radical,
L and L′ can be identical or different and are connecting organic moiety,
n and m can be identical or different and are integers selected as 1≦m+n<5,
the SiO_{1,5} are part of the inorganic part of the network.

14. A material according to claim 12 characterized in that L and L′, identical or different, are hydrocarbonated connecting moiety which can be linear, branched or include a cycle, which can be saturated or unsaturated, substituted or non-substituted, and which can include, in its chain or cycle, one or several oxygen, sulfur or nitrogen heteroatom and/or one or several groups chosen among —CO—, —CONH—, —COO—, —NHCO—, —N═N—, —S(O)—, —S(O)₂—, —P(═O)(ORa)—, with Ra being a C₁₋₈ alkyle.

15. A material according to claim 12 characterized in that L and L′ can be identical or different, and are defined from the Si atom to Y by the structure -L1-L2- in which L1 is chosen among the following groups in their bivalent form: C₁₋₂₀ alkyl, C₁₋₂₀ alkenyl, C₁₋₂₀ alkynyl, C₆-C₂₄ aryl, C₇-C₄₄ alkylaryl, C₇-C₄₄ alkenylaryl, C₇-C₄₄ alkynylaryl, the said groups being able to contain triazole and tetrazole units and being unsubstituted or substituted with one or more moieties selected from C₁₋₁₀ alkoxy, C₁₋₁₀ alkyl, C₁₋₁₀ aryl, amido, imido, phosphido, nitrido, C₁₋₁₀ alkenyl, C₁₋₁₀ alkynyl, arene, phosphane, sulfonated phosphane, phosphate, phosphinite, arsine, ether, amine, amide, imine, sulfoxide, carboxyl, nitrosyl, pyridine, substituted pyridine, imidazole, substituted imidazole, triazole, tetrazole, pyrazine, substituted pyrazine and thioether; and L2 is chosen among —O—, —NH—,
—N(C₁₋₆ alkyl)-, —N(phenyl)-, —N(benzyl)-, —C(O)—, —C(O)O, —OC(O)—, —S—, —SO₂—, N═N, —NHC(O)— and —CONH—.

16. A material according to claim 12 characterized in that m=1 and n=0 and, as a result, the organic molecules which include at least one radical are located in the pores of the material.

17. A material according to claim 12 characterized in that 2≦m+n and, as a result, the organic molecules which include at least one radical are located in the walls of the material.

18. A material according to claim 1 characterized in that the radical is a persistent radical.

19. A material according to claim 1 characterized in that the radical is chosen among nitroxyl, trityl and verdasyl radicals.

20. A material according to claim 12 characterized in that the organic-inorganic component (I) is chosen among:

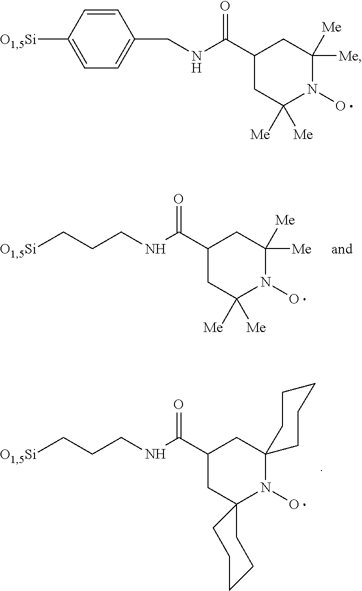

21. A material according to claim 12 characterized in that it corresponds to a material of formula (III): 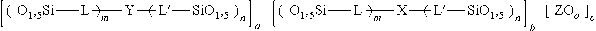
wherein
a, b and c can be identical or different and are integers selected as
a>0, 0≦b/a≦1000, and 1≦(a+b+c)/(a+b)≦1000,
the Z atom is selected from silicon Si, zirconium Zr, titanium Ti, aluminium Al, and o is 2 when Z is Si, Zr or Ti and o is 1.5 when Z is Al and L, L′, X, Y, m and n are as defined in claim 12.

22. A material according to claim 1, characterized in that the porous network is structured in an hexagonal array of the pores or in a cubic or wormlike arrangement of the pores.

23. A material according to claim 1, characterized in that it is in the form of a powder.

24. Method of analysis by Nuclear Magnetic Resonance (NMR) of one or more selected nuclei of an analyte of interest using dynamic nuclear polarization comprising the following steps of:
i) A sample is prepared by mixing a solution of the analyte with a material consisting in a porous network, this network being at least in part formed by inorganic oxide characterized in that the material comprises organic molecules which include at least one radical and which are covalently bonded to the network by at least one siloxy bonds,
ii) The sample is solidified,
iii) The solidified sample is polarized by microwave irradiation, the radical linked to the material allowing the generation of polarization of the analyte,
iv) The NMR spectrum of the selected nucleus (i) of the polarized analyte is recorded on the solidified sample.

25. A method according to claim 24 wherein the network is structured.

26. A method according to claim 24 wherein the network is formed with a sol-gel step using an organosilane for the introduction of the organic molecules allowing their regular distribution within the porous material.

27. A method according to claim 24 wherein the organic molecules which include at least one radical and which are covalently bonded to the network by two or three siloxy bonds.

28. A method according to claim 24 wherein the material used for generating the structuration is a material in a porous and structured network being at least in part formed by Si atoms, or Si atoms and metal atoms, linked to each other's by oxy bridges, characterized in that the material comprises organic molecules which include at least one radical and which are covalently bonded to the network via siloxy bonds, the amount of radicals ranging from 0.50 to 0.03 mmol of radical per gram of material, and in that the network is formed with a sol-gel step using an organosilane for the introduction of the organic molecules allowing their regular distribution within the porous structured material.

29. A method according to claim 24 wherein the analyte comprises any spin 1/2 nuclei such as ¹H, ¹³C, ³¹P, ¹⁵N, ²⁹Si and/or ¹⁹F atoms and/or quadripolar nuclei such as ²⁷Al which are analyzed.

30. A method according to claim 24 wherein both steps iii) and iv) or steps ii), iii) and iv) are performed in an NMR spectrometer.

31. A method according to claim 24 wherein the sample is solidified at a temperature in the range from 1K to 300 K, and preferably from 50 K to 200 K.

32. Method of analysis by Nuclear Magnetic Resonance (NMR) of one or more selected nuclei of an analyte of interest, wherein it uses dynamic nuclear polarization generated with a material according to claim 1.

33. A method according to claim 32 wherein the analyte comprises any spin 1/2 nuclei such as ¹H, ¹³C, ³¹P, ¹⁵N, ²⁹Si and/or ¹⁹F atoms and/or quadripolar nuclei such as ²⁷Al which are analyzed.

34. A method according to claim 32 comprising the following steps of: x) A sample is prepared by mixing a solution of the analyte with a material in a porous and structured network being at least in part formed by Si atoms, or Si atoms and metal atoms, linked to each other by oxy bridges, characterized in that the material comprises organic molecules which include at least one radical and which are covalently bonded to the network via siloxy bonds, the amount of radicals ranging from 0.50 to 0.03 mmol of radical per gram of material, and in that the network is formed with a sol-gel step using an organosilane for the introduction of the organic molecules allowing their regular distribution within the porous structured material,
xx) The sample is polarized by microwave irradiation, the radical linked to the material allowing the generation of the polarization,
xxx) The NMR spectrum of the polarized analyte is recorded.

35. A method according to claim 34 wherein the sample is solidified before polarization and the polarization of the step xx) is performed on the sample in a solidified state.

36. A method according to claim 35 wherein the irradiation of the step xx) is also performed on the sample in a solidified state.

37. A method according to claim 35 wherein both steps xx) and xxx) are performed in an NMR spectrometer.

38. Process for the preparation of a material according to claim 1 comprising the following steps:
a) a sol-gel step involving at least two precursors:
a tetraalkoxysilane, tetrahydroxysilane,
alkoxymetal, hydroxymetal, alkoxyhydroxysilane, alkoxyhydroxymetal, silicate or metallate in which the metal is Zr, Ti or Al,
and an organosilane corresponding to a monosilyl or a polysilyl entity, for instance chosen among the organotrialkoxysilanes, organotrichlorosilanes, organotris(methallyl)silanes, organotrihydrogenosilanes, di-organosilane such as diorganodialkoxy or dichlorosilane, or disilyl compounds of general formula X₃Si—R′—SiX₃ with X=halogen, alkoxy, hydroxyl, methallyl or hydrogen, the selected organosilane carrying the organic moiety which includes at least one radical or carrying a reactive function allowing, in one or several additional step(s), the introduction of the organic molecules which include at least one radical,
this sol-gel step being performed with a structure directing agent, for obtaining a porous and structured network,
b) when the step a) uses a trialkoxysilane carrying a reactive function, one or several additional step(s) are conducted for obtaining the covalent link of the organic molecules which include at least one radical on the inorganic network.

39. Process according to claim 38, wherein the step a) uses an organosilane carrying a reactive function selected from halogen atoms and functional groups such as azide, amine, amide, imine, nitrosyl, carboxyl, ketone, aldehyde, phosphine, phosphate, phosphinite, sulfoxide, —OH, —SH, and ether.

40. Process according to claim 39, wherein the step a) uses an organosilane carrying an azide function, which is further transformed in an NH₂ function, on which a reaction is carried with an organic molecule which includes at least one radical and a carboxyl group in order to form a NH—CO link.

41. Process according to claim 38, wherein a further step is included after the step a) or b) which consists in removing the residual hydroxyl or alkoxy groups.

42. Process according to claim 38, wherein a further step is included after the step a) or b) which consists in removing the structure directing agent.

43. Process according to claim 42, wherein the structure directing agent is removed by washing with water or a proper polar solvent chosen among alcohols, amides, ethers and esters with/without the presence of an acid and/or a base, with or without a Soxhlet extraction.

44. Process according to claim 42, wherein the structure-directing agent is removed by a Soxhlet extraction with aqueous HCl and pyridine.

45. Process according to claim 38, wherein the step a) is achieved, with a structure directing agent, in water with or without at least one co-solvent, or in an appropriate polar solvent along with water, using hydrolysis-condensation catalysts chosen among bases, acids or nucleophilic compounds.

46. Process according to claim 38, wherein the step a) is achieved, with a structure directing agent, in water with at least one co-solvent chosen among alcohols, amides, ethers, esters.

47. Process according to claim 38, wherein the step a) is achieved, with a structure directing agent, in a polar solvent chosen among alcohols, amides, ethers and esters.

48. Process according to claim 38, wherein the structure directing agent is chosen among:
1) anionic surfactants (sodium dodecyl sulfate);
2) cationic surfactants: ammonium salts (cetyltrimethylammonium bromide), imidazolium salts (1-hexadecane-3-methylimidazolium bromide, pyridinium salts (n-hexadecylpyridinium chloride), phosphonium salts;
3) non-ionic surfactants:
amines (hexadecylamine (C₁₆H₃₃NH₂)),
alkylpolyethyleneoxides or alkylarylpolyethylene oxides (preferably C₁₆H₃₃O(CH₂CH₂O)₂H, C₁₁₋₁₅H₂₃₋₃₁O(CH₂CH₂O)₁₂H, C₁₄H₂₂O(C₂H₄O)ₙH, n=9-10), p-C₈H₁₇C₆H₄O(CH₂CH₂O)₁₀H, C₁₂H₂₅O(CH₂CH₂O)ₙH n˜2, 4, 8),
polysorbate surfactants (polyoxyethylene (20) sorbitan monolaurate) and,
amphiphilic block copolymers (preferably triblock copolymers such as EO₂₀-PO₇₀-EO₂₀, EO₁₀₀-PO₇₀-EO₁₀₀ or such as EO₁₃₂-PO₅₀-EO₁₃₂).

49. Process according to claim 38, wherein the step a) is achieved with an hydrolysis polycondensation catalyst which is a base chosen among amines; or an acid chosen among inorganic acids such as hydrochloric acid, hydrobromic acid, iodidric acid . . . and organic acids such as p-toluene sulfonic acid; or a nucleophile such as sodium fluoride, tetrabutylammonium fluoride.

50. Use of a material according to claim 1 as an electron source for dynamic nuclear polarization.

51. Use of a material according to claim 1 for catalysis reactions like oxidation reactions.
